(19) United States
(12) Patent Application Publication
(10) Pub. No.: US 2010/0266153 A1
(43) Pub. Date: Oct. 21, 2010

(54) ELECTRONICALLY COMPENSATED MICRO-SPEAKERS AND APPLICATIONS

(76) Inventors: Garth W. Gobeli, Albuquerque, NM (US); Stephen L. Mills, Albuquerque, NM (US)

Correspondence Address: RODEY, DICKASON, SLOAN, AKIN & ROBB, PA, P.O. BOX 1888, ALBUQUERQUE, NM, 87103, US

(21) Appl. No.: 12/423,990

(22) Filed: Apr. 15, 2009

(51) Int. Cl. H04R 25/00; H03G 5/00

(52) U.S. Cl. 381/321; 381/101

(57) ABSTRACT

Electronics for altering the audio frequency response of a micro-speaker without modifying the micro-speaker itself; the micro-speaker having a resonant peak region. In one embodiment the electronics includes a first circuit for flattening the frequency response curve up to the resonant peak region, and a second circuit for flattening the frequency response curve for audio frequencies higher than this region. Preferably, the extent of the flattened response over such range of frequencies is in the range of plus or minus 3 dB. The first circuit includes one of the group consisting of a high pass filter and a low pass filter, while the second circuit includes the other of this group. Each filter yields an integer multiple of 6 dB per octave slope. In another embodiment, for correcting hearing loss, a high pass filter is connected to the micro-speaker to progressively attenuate the frequency response curve as the frequency decreases.

### FIELD OF THE INVENTION

This invention pertains to the electronic compensation of the existing micro-speakers contained in earphones or earbud headsets. The compensation is designed to modify the normal micro-speaker output as a function of acoustic frequency so as to: (1) produce a desired response (e.g. to an essentially flat, frequency independent response); or (2) provide a frequency response that can compensate for the hearing deficiency of users, usually elderly, that are hearing impaired.

### BACKGROUND OF THE INVENTION

The micro-speakers being addressed in this disclosure are those contained in earbuds/earphones used with personal audio devices such as I-Pods, MP3 players, etc. These micro-speakers usually have a diameter of 9 mm to 11 mm and their acoustic frequency characteristic is characterized by a maximum in the response that is in the range of 2000 Hz to 4000 Hz. The micro-speaker response declines for all micro-speakers at frequencies both higher and lower than the maximum by as much as 25 dB at 300 Hz and 25 dB at 10,000 Hz.

Considerable effort has been expended by various manufacturers to improve the earbud/earphone frequency response curves. This work has resulted in devices that show smaller reductions in response at both high and low frequencies while at the same time moving the peak response of the micro-speaker to higher frequencies (as high as 4000 Hz.). All these efforts have concentrated on mechanical approaches. As the response curve becomes flatter the price of the earbuds increases, sometimes to several hundreds of dollars. Parenthetically, the cheap end of the earbud market is at about one dollar.

U.S. Patent Application Publication (“USPAP”) US2007/0258598 describes a method of characterizing the parameters of a micro-speaker (i.e., the frequency output characteristics). Those parameters describe the functionality of the micro-speaker itself but do not address methods of significantly changing or improving the basic micro-speaker properties. This application details how an existing earbud/earphone system's parameters (not otherwise defined) can be changed/modified by using an algorithm to select a designated parameter of the micro-speaker and optimize it by the change in other different parameters. An example is given in FIG. 5 of this application in which the sharp spikes in the frequency spectrum of a micro-speaker are suppressed by this parameter optimization method. The sharp spikes are probably due to high order mechanical coupling effects. No effort is made to modify the fundamental response spectrum of the micro-speaker.

USPAP US2006/0140418 shows a method of compensating the frequency of an acoustic system. It uses digital signal processing and it relates to the “jazz”, “modern rock”, etc. modes of changing the output of a portable sound system (not otherwise defined). It also discusses the possibility of modifying the “acoustic characteristics of a user” by use of a computer-audio generator-headphone system. This fitting to a specific user does not reflect the mode of modification or the intent of this disclosure.

USPAP US2007/0098186 describes a “tone control” for a hearing aid, sound equipment and the like. The figures in this reference are typical audio amplifier tone controls (i.e., a type of “graphic equalizer”). No mention is made, nor is there discussion of the effects of the non-uniform properties of the micro-speaker of a hearing aid or how such non-uniform response is to be corrected.

U.S. Pat. No. 3,927,279 shows a method of tailoring the electronic design of a series of amplifiers and filters to modify the output spectrum of a hearing aid. The data, shown as FIG. 6, show a maximum gain of about 25 db from 300 Hz to 1500 Hz for a control voltage of 0.9 volts. Both the spectrum and the maximum gain shown are consistent with an uncorrected micro-speaker with a battery voltage of about 1 volt. The maximum overall gain is reduced as the battery voltage is reduced due to drain on the battery that lowers the nominal voltage. No mention is made of methods for extending the amplifier output to useful values at higher frequencies (above 3000 Hz).

U.S. Pat. No. 5,475,759 speaks to the reduction of the feedback problem that causes an aggravating squeal when the gain is advanced to a very high value. A filter system is used to address the problem by utilizing two channels from an input and using one of them to provide an adaptive method to suppress the unwanted feedback component. Again, no discussion is offered concerning the response of the micro-speaker to acoustic signals of differing frequencies.

U.S. Pat. No. 4,926,139 uses a set of 4 pole filters that have a 24 db/octave filter roll off, together with an ACG circuit to tailor the resultant output to match the hearing deficiency of individual hearing aid users. This approach uses DSP components and sophisticated logic for its purpose. This patent does not address changing the spectrum of a micro-speaker.

U.S. Pat. Nos. 5,663,727, 7,466,829, 7,433,481, 4,792,977, and 4,887,229 are directed to digital hearing aids and methods used to improve the fit to individual users. None of them discuss correcting the micro-speaker response spectrum.

It is the object of this invention to provide a simple and direct means for changing/modifying the output audio spectrum of a variety of micro-speakers that are currently manufactured by a plethora of entities.

It is a further object of this invention to provide a methodology based on the design of multiple electronic filters for changing the basic output spectrum of micro-speakers.

It is a further objective of this invention to provide a straightforward method of correcting the typical micro-speaker response by the careful and judicious use of a set of high-pass and low-pass filters.

### SUMMARY OF THE INVENTION

Current micro-speakers usually have diameters of 9 mm to 11 mm, with 10 mm being the most common. FIG. 1, described below, shows the audio frequencies of a number of micro-speakers currently being manufactured. To facilitate comparison, all data have been normalized so that their peak intensities are positioned at the same amplitude. This invention shows that by the judicious use of filters using a combination of resistances (R) and capacitances (C) with an amplifier network, a desired, essentially flat (independent of audio frequency) micro-speaker response curve can be provided. Any of the response curves shown in FIG. 1 can be so modified by changing the values of resistances and/or capacitances to provide an essentially flat audio response over the frequency range from 100 Hz to at least 10,000 Hz.

A second type of micro-speaker response would be that which is needed to closely approximate a correction for the strong decline in hearing at high frequencies that is experienced by most elderly individuals. This loss of hearing at high frequencies is denoted as presbyacusis or sensorineural hearing loss. This presbyacusis or sensorineural hearing loss that is widely prevalent in the elderly is the most common type of hearing loss. A U.S. Army study conducted in 1980 indicates that 70% to 80% lose their hearing in a consistent pattern that can be predicted by age. Currently it is estimated that the hard-of-hearing population in the United States numbers about 31,000,000, with about 22% owning needed hearing aids.

By judicious selection of resistance and capacitance values used in the various filter sections of this invention, it is possible to approximately correct such hearing deficiencies for the vast majority of such hearing impaired individuals with a single compensation system. The truly attractive feature of such an approach is that it is “one-size-fits-all” in that a compensated earbud micro-speaker system fashioned in accordance with this invention only requires a user adjusted volume control and the user can compensate for hearing losses over a quite wide range of impairment. This fact results in a simple-to-manufacture device that offers impressive assistance to the hearing impaired at a cost that is a small fraction of the price of current hearing aids.

It should be understood that, in the disclosed embodiments, the micro-speaker itself is an off the shelf component and the frequency response curve of such micro-speaker as manufactured is not modified. The frequency response curve is changed (e.g., essentially flattened) by altering the signal to the micro-speaker by the use of one or more of the filters of the present invention. Thus, the altered frequency response is achieved by the combination of micro-speaker and the associated filter circuit. However, as the altered signal emanates from the micro-speaker, for the purpose of describing the embodiments of this invention the response of the system is generally referred to as the response of the micro-speaker (e.g., flattening the audio frequency response curve of the micro-speaker).

### BRIEF DESCRIPTION OF THE DRAWINGS

The invention will become readily apparent from the following detailed description that refers to the accompanying drawings:

FIG. 1 A graph of Log Audio Intensity (dB) vs. Log Audio Frequency for 5 manufacturer's earbud micro-speakers, wherein the resonant peak region for all such speakers is normalized to 0 dB.

FIG. 2 A diagram of the circuit of the first embodiment of the present invention used to achieve an essentially flat micro-speaker response.

FIG. 3 A plot of micro-speaker #16 (FIG. 1) with flat compensation by using the circuit of FIG. 2.

FIG. 4 A typical audiogram of a person with moderate to deep presbyacusis (sensorineural or old-age hearing loss).

FIG. 5 A diagram of circuits of the second embodiment of the present invention used to provide micro-speaker compensation to correct hearing loss shown in FIG. 4.

FIG. 6 A chart showing basic micro-speaker response, the 6 dB/octave high pass filter, and the resultant micro-speaker filtered response.

FIG. 7 A chart showing the resultant micro-speaker response of FIG. 6, the audiogram of FIG. 4; and the resultant users hearing response curve.

FIG. 8 A plot of Insertion gain in dB vs. audio frequency on a linear frequency scale for the ZON line of advanced hearing aids of Starkey Mfg.

FIG. 9 A schematic layout of a hearing aid that uses two circuits of FIG. 5.

### DETAILED DESCRIPTION OF THE INVENTION

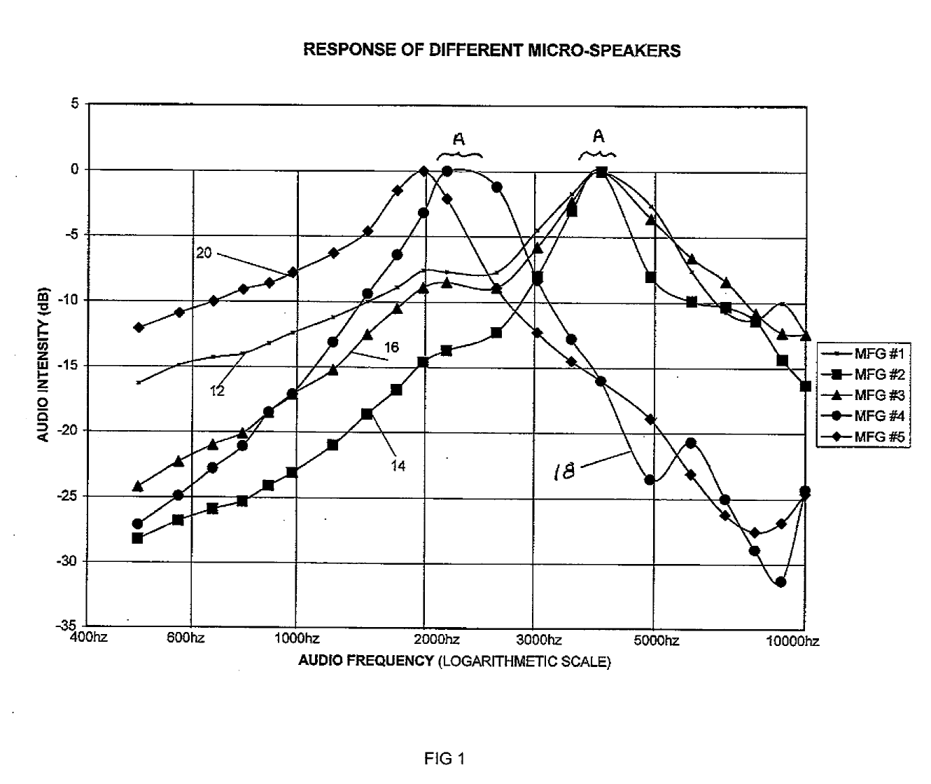

The experimentally measured output acoustic spectra of some commercially available earbud micro-speakers are illustrated in FIG. 1 for five different manufacturers (12, 14, 16, 18, and 20). Note that each speaker has a resonant peak region (A) in the audio intensity as a function of audio frequency. The location of each resonant peak region lies between 2000 Hz and 4000 Hz, with the more expensive earbud micro-speakers being at the high frequencies. In all cases shown in FIG. 1, the response declines for frequencies both higher and lower than the resonant peak region. This type of response as a function of frequency is due to the resonant vibration of the diaphragm of the micro-speaker. The ideal response for any speaker is that of a flat, frequency independent relationship. From an audio listener's view, curve 12 shows the smallest variation over the entire frequency region shown, and would be judged to be the “best” micro-speaker. The responses of some micro-speakers have been improved by careful mechanical design, reducing the thickness of the speaker diaphragm, and careful attention to the characteristics of the grill covering of the speaker.

### Compensation of Micro-Speakers to Realize a Flat Frequency-Independent Response

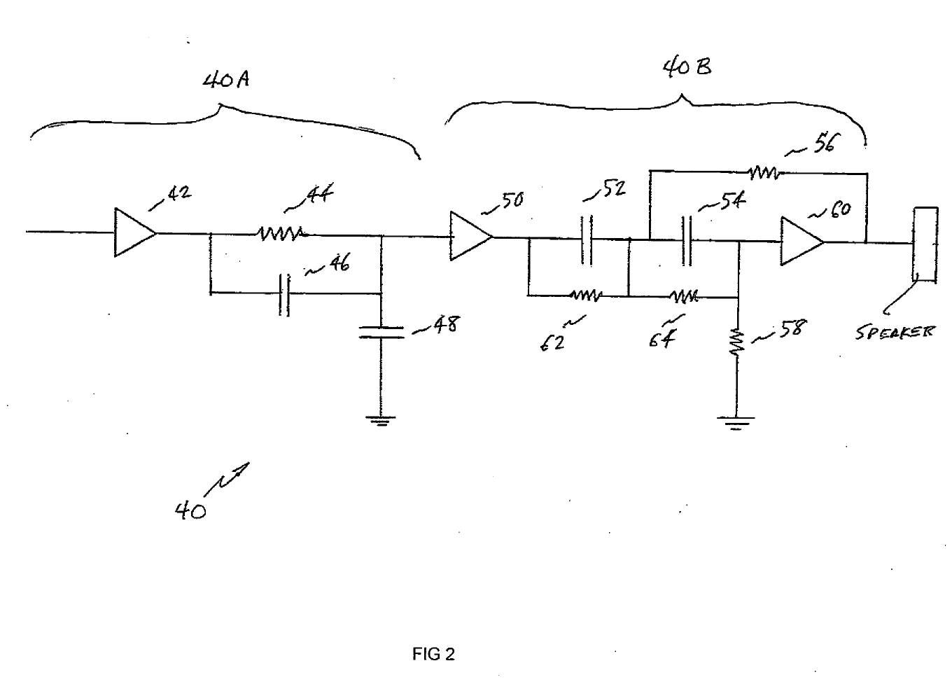

FIG. 2 shows the amplifier/filter circuit used to compensate a micro-speaker fundamental characteristic into an essentially flat response. The normalizing filter circuit (40) is comprised of a buffered and modified low-pass filter section (40A) followed by a buffered and modified high-pass filter section (40B). Inflection points in the frequency response curve of each filter section are selected by component values so as to normalize or correct the natural resonant peaking of the frequency response curve of the micro-speaker whose fundamental characteristic is to be flattened. For most micro-speakers, as frequency increases, the rising slope of the output response, which occurs below the resonant peak region, is less severe than the falling slope of the output response, which occurs above peak resonance. Consequently, the rising slope is corrected by a filter section with a 6 dB per octave slope, and the falling slope is corrected by a filter section with a 12 dB per octave slope. (A decibel is a unit of audio intensity that is logarithmic in scale, that is when the sound level increased or decreased by a factor of 2 then the level has increased or decreased by 6 dB. An octave represents the doubling or halving of an audio frequency.)

A signal voltage passes through a buffer amplifier (42) and is presented to a modified low-pass filter section (44, 46, 48). A resistor (44) and capacitor (48) constitute a standard first-order low-pass filter section with an inflection point at a low frequency below which there is negligible attenuation. Above this frequency there is an increasing attenuation of 6 dB per octave. The standard filter action is modified by the addition of a second capacitor (46) in parallel with the resistor (44) which causes the 6 dB per octave attenuation to cease at a second inflection point which is at a higher frequency. The frequency of the second inflection point for this filter section is chosen to be near the resonant frequency of the micro-speaker which is being normalized.

The signal voltage passes through a second buffer amplifier (50) and is presented to a modified high-pass Sallen-Key filter section (52, 54, 56, 58, 60, 62, 64). Two resistors (56, 58) and two capacitors (52, 54), together with a buffer amplifier (60), constitute a standard second-order high-pass Sallen-Key filter section with an inflection point at a high frequency above which there is negligible attenuation. Below this frequency there is an increasing attenuation of 12 dB per octave. The standard filter action is modified by the addition of two additional resistors (62, 64) in parallel with the two capacitors (52, 54) which causes the 12 dB per octave attenuation to cease at a second inflection point which is at a lower frequency. The frequency of the second inflection point for this filter section is chosen to be near the resonant frequency of the micro-speaker which is being normalized.

Buffer amplifiers (42, 50, 60), or their equivalents, are required to drive the filter elements at the input of each filter section with a low impedance and buffer the output of each filter section, thereby preventing interaction which would alter filter performance. The buffer amplifiers (42, 50, 60) shown are typically unity gain. Non-unity gain amplifiers can also be employed. If the final buffer amplifier (60) is operated at non-unity gain, an adjustment of the resistor and/or capacitor values of the modified Sallen-Key high-pass filter section is necessary to avoid changing the damping response of the filter section. The power for this electronic design is supplied by a rechargeable Lithium-Ion battery that operates at a nominal voltage of 3.7 volts.

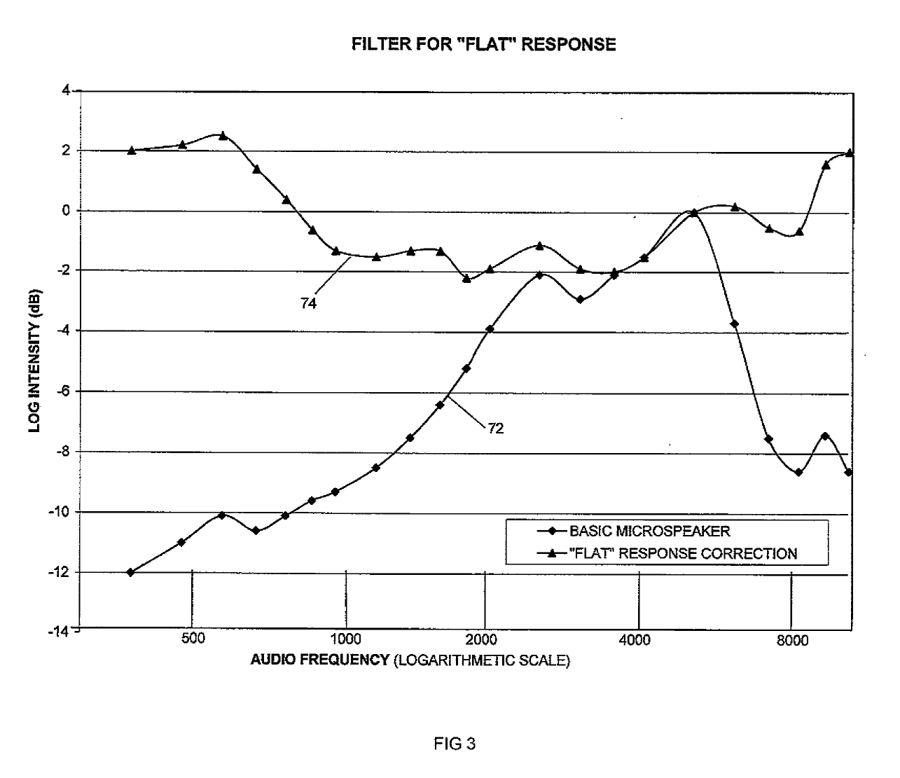

Using the electronic design illustrated in FIG. 2 changes the micro-speaker response curve 72 of FIG. 3 into the curve 74 of FIG. 3. It is clear that this curve is essentially flat in that the deviation from being truly flat is in the range of no more than plus-or-minus 3 dB, whereas the accepted range of a person with excellent hearing for speech is plus-or-minus 10 dB. The audio intensity has been changed by a maximum of 14 dB for this particular micro-speaker. A person listening to music or speech on I-Pods or MP3 Players would perceive the acoustic output of such devices as being much more realistic and enjoyable when such a frequency compensated earbud system is used.

### Compensation of Micro-Speakers for High Frequency Enhanced Performance

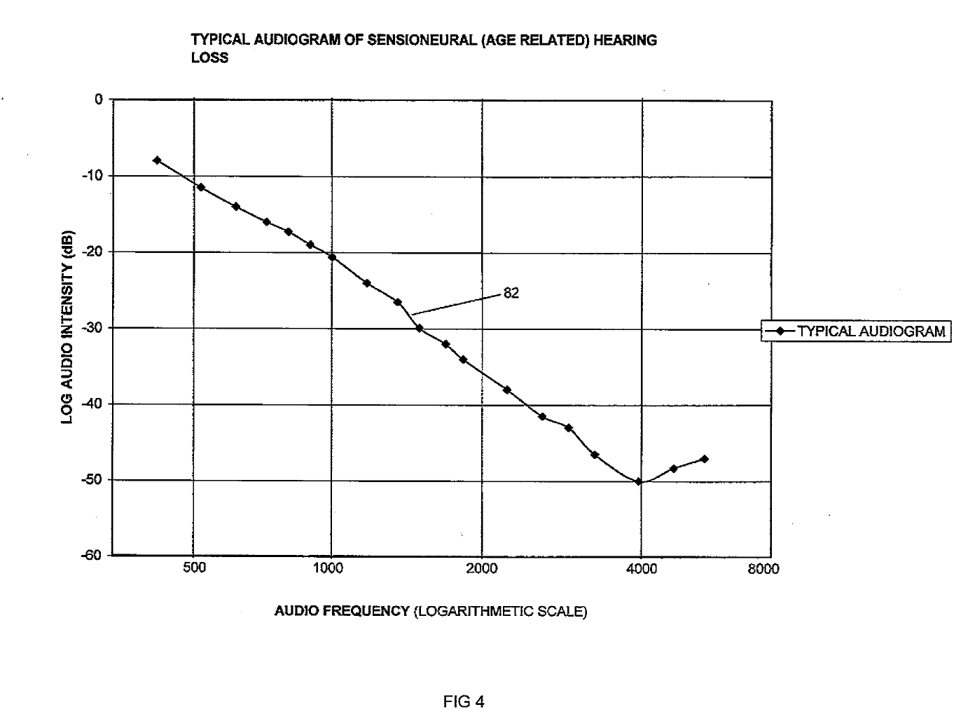

Another excellent use for a compensated micro-speaker is to filter the basic micro-speaker response vs. audio frequency to provide a continuously higher output as the frequency increases. Such a system would then provide compensation to the common sensorineural hearing loss of the elderly. (This type of high-frequency hearing loss is alternately called presbyacusis and is synonymous with the aging process.) This hearing loss is illustrated in FIG. 4, curve 82 which gives a typical hearing audiogram for a moderate to significant hearing impairment. This audiogram is plotted as LOG of the Audio Intensity (conventionally shown as decibels, dB), as a function of the LOG of the audio frequency. The curve for a very large percentage of the hearing impaired population is characterized by the linear nature of the hearing loss in terms of loss in dB per octave frequency change. This plot of an individual's hearing loss is named an audiogram. It is estimated that 70% to 80% of hearing loss in the elderly is represented by an audiogram that is very similar to that shown in FIG. 4. The difference between individuals lies in the exact slope of the approximately straight line. The steeper the line the greater is the hearing loss. The severity of a person's hearing loss is sometimes described by the lowest point on the audiogram. The loss at a frequency, for example at 4000 Hz, can be 40 dB for mild hearing loss to 80 dB for profound hearing loss. The indicated loss shown by curve 82 is about 50 dB. The “hook” or “dip” at the high frequency end of the audiogram indicates that part of this individual's hearing loss is due to some type of damage to the ear, such as a loud noise environment, shooting, etc.

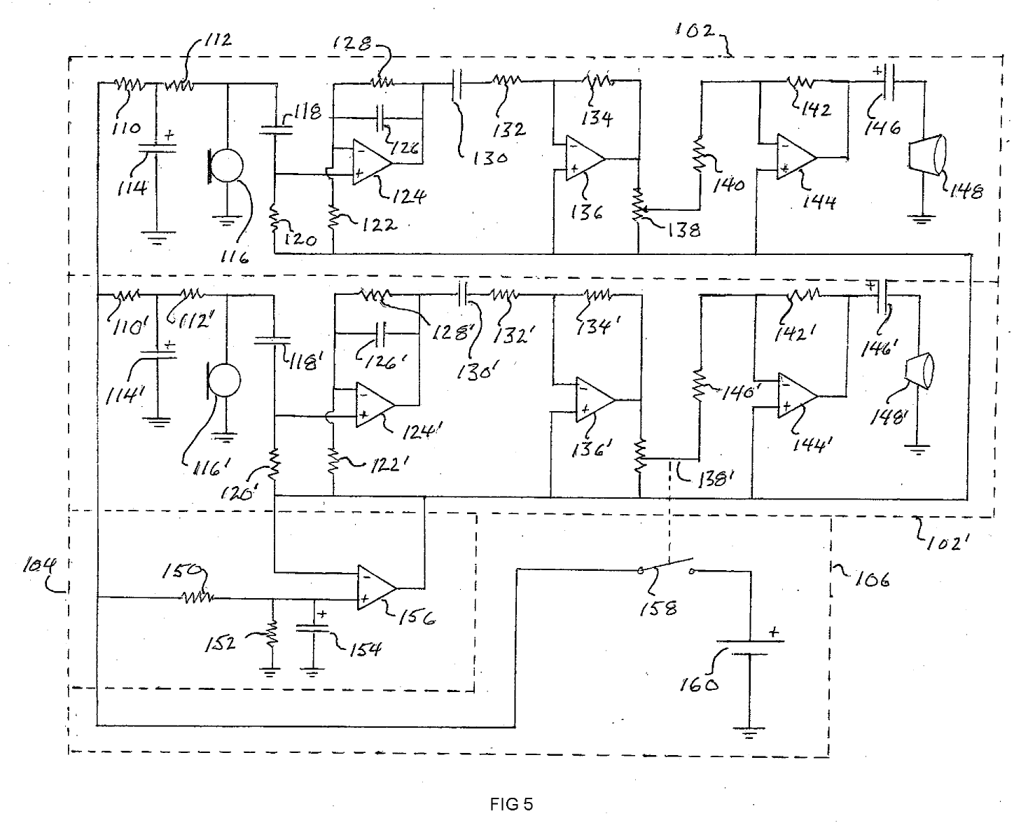

The solution to this hearing loss problem then is to provide a set of amplifiers-filters that will restore the person's hearing spectrum to approximately a flat response. The specific type of micro-speaker for efficiently making this correction is selected from FIG. 1, and the best choice is 12. This is due to the overall small decline in audio intensity from the peak at 4000 Hz to both 400 Hz and 8000 Hz. Examination of this curve shows that the low frequency decline is between −3 dB/octave and −4 dB/octave and the high frequency decline is about 6 dB/octave. The correcting amplifiers/filters are shown in FIG. 5.

The hearing aid circuit (100) is comprised of several sections: a power source (106), a bias circuit (104), and right and left channels (102, 102′). The left channel (102′) is a duplication of the right channel (102), and descriptions given of the operation of the right channel (102) will pertain to the left channel (102′) as well.

In the power source section (106), a rechargeable Lithium-Ion battery (160) supplies power at a nominal 3.7 volts to the rest of the circuitry through a switch (158).

In the bias circuit section (104), two resistors (150, 152) of equal value constitute a voltage divider which yields a voltage at one-half of the battery voltage. A capacitor (154) filters the resultant voltage so as to minimize systemic noise and obviate any possible systemic feedback via the power source buss. The filtered voltage is presented to the non-inverting input of an operational amplifier (156) which is configured for unity gain. The output of the operational amplifier (166) thereby presents a buffered low impedance bias voltage to circuitry in the right and left channels (102, 102′). The bias voltage causes the amplification circuitry within the right and left channels (102, 102′) to operate proximal to a voltage centered at one-half of the battery voltage, thereby allowing voltage excursions consequent to the normal action of signal amplification to be maximized without clipping.

In the right channel section (102), the power source voltage is conditioned by a filter circuit comprised of a resistor (110) and capacitor (114) so as to minimize systemic noise and obviate any possible systemic feedback via the power source buss. The conditioned voltage is presented to an electret microphone module (116) via a bias resistor (112). Acoustical pressure incident to the microphone module (116) causes it to develop a signal current which flows through the bias resistor (112) causing a signal voltage to develop across the resistor. The signal voltage is coupled to the non-inverting input of an operational amplifier (124) in an amplification stage (120, 122, 124, 126, 128) via a capacitor (118). The capacitor (118) and resistor (120), which are connected to the operational amplifier (124) non-inverting input, constitute a high-pass filter and are sized to pass only signals at or above the lowest frequency of interest, which in this case is about 50 Hz. The capacitor (126) and resistor (128), which are connected between the output and the inverting input of the operational amplifier (124), constitute a low-pass filter and are sized to pass only signals at or below the highest frequency of interest, which in this case is about 16 kHz. The pass-band gain of the amplification stage is set by the approximate ratio of two resistors (122, 128), which in this case is about 100. The amplified signal is coupled to the inverting input of an operational amplifier (136) in the next amplification stage (132, 134, 136) via a capacitor (130). The capacitor (130) and resistor (132) which are connected to the operational amplifier (136) inverting input constitute a high-pass filter and are sized to progressively attenuate, at a slope of 6 dB per octave, signals below a chosen inflection point set at a high frequency, which in this case is about 10 kHz. The pass-band gain of the amplification stage is set by the approximate ratio of two resistors (132, 134), which in this case is about 100. The amplified signal is passed to the inverting input of a high current output operational amplifier (144) in the final amplification stage (140, 142, 144) via a variable resistor (138) which serves as a volume control. The pass-band gain of the amplification stage is set by the approximate ratio of two resistors (140, 142), which in this case is about 10 when the rotational shaft of the variable resistor (138) is positioned to its fully clockwise setting. The final amplified signal is coupled to the micro-speaker (148) via a capacitor (146). The capacitor (146) together with the electrical impedance of the micro-speaker (148) constitute a high-pass filter and are sized to pass only signals at or above the lowest frequency of interest, which in this case is about 50 Hz.

In this embodiment of the invention, surface mount components are used for all capacitors, fixed value resistors, and operational amplifiers. Polarized capacitors (114, 146, 154) are tantalum; non-polarized capacitors (118, 126, 130) are NP0 ceramic. At the bias circuit, input amplification stage, and middle amplification stage, the operational amplifiers (124, 136, 156) are low noise, low power supply voltage types such as National Semiconductor LMP7732. The output operational amplifier (144) has high current and rail-to-rail output drive capabilities such as ST Electronics TS482. Electret microphone modules (116) are low noise types with a built-in field effect transistor buffer/amplifier such as Panasonic WM61A.

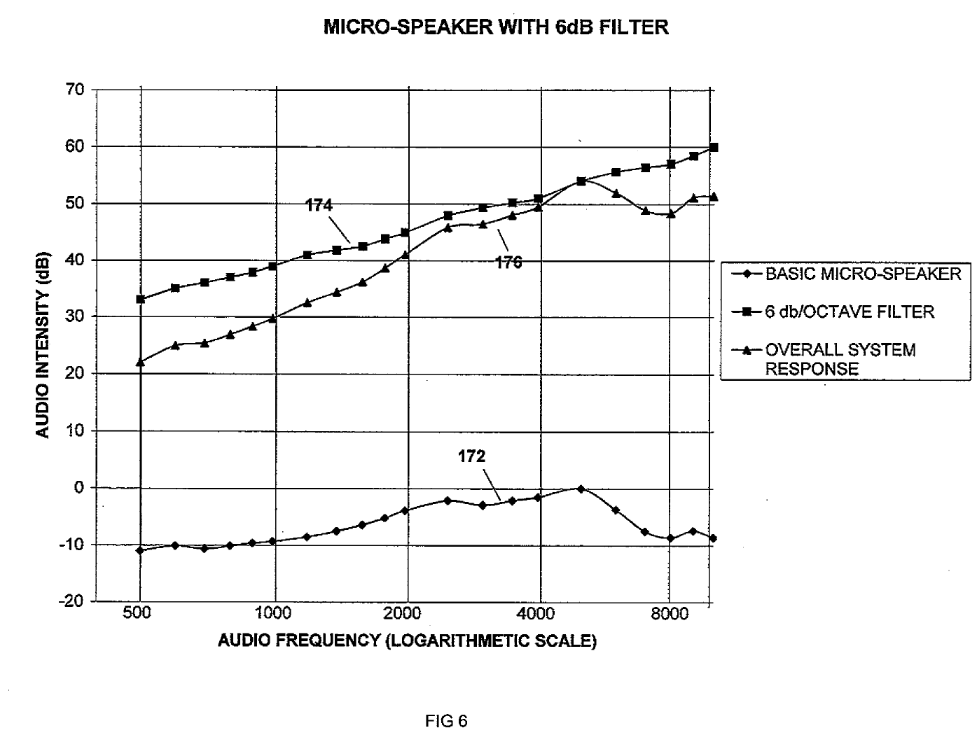

FIG. 6 shows the effect on the basic measured micro-speaker response (curve 172) by adding the modified response obtained with the amplifier/filter set of FIG. 5 (i.e., curve 174). The resultant final compensated output of the filtered micro-speaker is then curve 176. Note that the magnitude of the signal at 10,000 Hz requires an overall gain of 60 dB or more at 10,000 Hz. With the rechargeable Lithium-Ion battery (that has a nominal output of 3.7 volts) the achievable gain is about 90 dB, but feedback problems currently limit the useable gain to about 80 dB. Note that the scale on this figure is different from the scale used in FIG. 1 and FIG. 2.

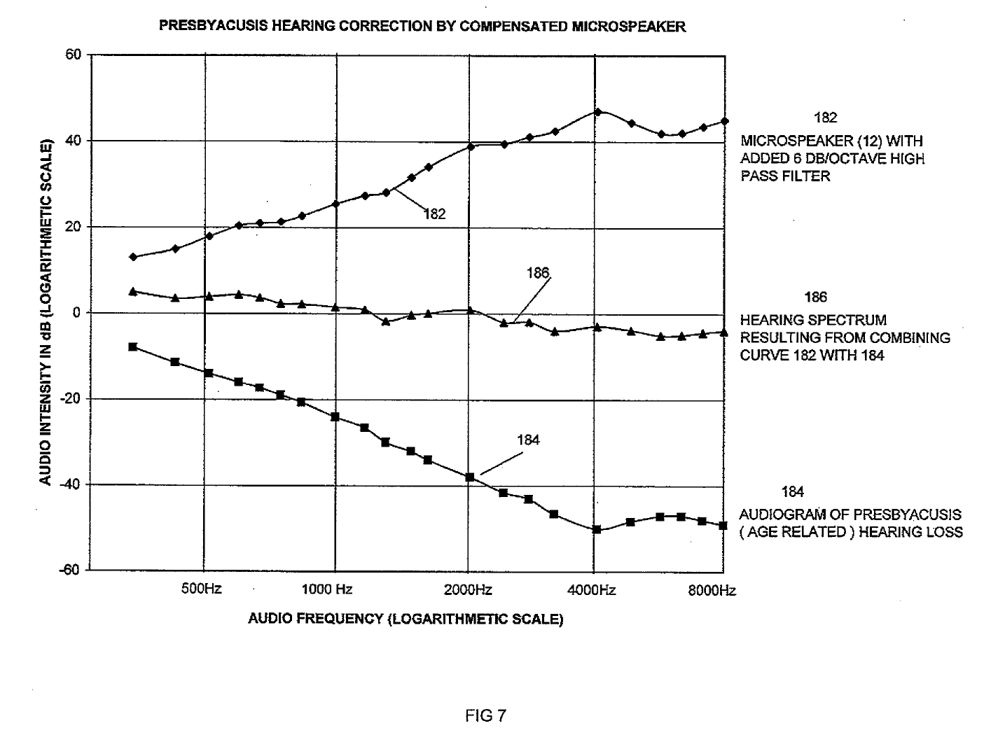

FIG. 7 shows the effect of adding the compensated micro-speaker response curve 182 (curve 176 from FIG. 6) to the audiogram 184 (curve 82 from FIG. 4). Curve 186 shows the resultant perceptive hearing of the individual from whom the audiogram was taken. Note that the slope of the compensated frequency response curve approximates the mirror image of the audiogram, such that the perceptive hearing of the individual from whom the audiogram was taken is well within the range of normal hearing (plus or minus 10 dB) and, in the illustrated embodiment, essentially flat. Note also that the vertical scale of this figure is much different from the earlier figures (e.g., FIG. 6). Thus, for instance, while curve 182 appears stretched vis-a-vis curve 176, the two are in fact the same.

The striking feature of this curve 186 is that the hearing level for this audiogram has been corrected to plus-or-minus 5 dB over the entire hearing frequency range of 400 Hz to 10,000 Hz. (The accepted range of normal hearing is specified as plus-or-minus 10 dB.) It has been found that the additional voltage offered by using 3.7 volt Lithium Ion batteries versus the 1.1 volt ZnO standard hearing aid batteries permits the amplification of the heavily filtered system to be sufficient to restore hearing for frequencies above 4000 Hz. It is not possible to provide this high frequency hearing for such a heavily filtered system when 1.1 volt batteries are used. Current hearing aid designs simply do not provide this magnitude of gain. They are currently limited to not more than 29 to 32 db, usually at the peak frequency of the micro-speaker/transducer that is used. The gain at frequencies above 4000 Hz is minimal and in some cases actually detrimental to hearing at these frequencies relative to the peak response near 3500 Hz.

The importance of restoration of the higher audio frequencies for presbyacusis, age related hearing loss, is dramatically illustrated by work on directional hearing and localization of sound. See External Ear Response and Sound Localization, E. A. G. Shaw, Localization of Sound: Theory and Applications, Symposium Convened at the University of Guelph, July 1979, Amphora Press. This reference shows measurements of the ear to sound of various frequencies that originate at different angles to the ear. These data exhibit a common response for frequencies from 2000 Hz to about 3500 Hz that are characterized by an increase in response from low to high frequencies. When the measurements are extended to higher frequencies, from 3500 Hz to 15000 Hz, a series of large amplitude swings are found that are sharp in character. These swings occur at different positions as the angular location of the sound source is changed relative to the ear. This behavior is so marked that the author, E. A. G. Shaw, comes to the conclusion that: “It is now beyond doubt that median-plane and monaural localization are closely linked with the direction-dependent filtering of sound by the external ear which occurs at frequencies greater than 4 kHz”.

That the dependence of directional hearing is strongly dependent on hearing high frequencies (greater than 3500 Hz) is buttressed by the physics of the frequency dependence of sound passing through an aperture. In this analysis, the ear forms the aperture through which sound is passed and somewhat focused. The equation that determines the angle at which sound is diffracted in passing through this aperture is given by the following equation:

Θ=1.22*λ/D (1)
Where Θ is the angle into which the sound radiation is refracted in radians 2π radians=360 degrees; 1 radian=57.3 degrees
   λ is the wavelength of the sound in meters
   D is the diameter of the aperture (the ear conch) in meters. The average ear is about 0.05 meters in extent (about 2 inches.
      The wavelength is determined by:

V=λ*F (2)
Where V is the sound velocity in air (V=330 m/sec²)
   F is the sound frequency in Hz.
      Then the following table can be constructed:

| | | |
|---|---|---|
| Sound Frequency | Wavelength | Diffraction Angle |

| (Hz) | (meters) | (Radians) | (Degrees) |
|---|---|---|---|
| 250 | 1.32 | 26.4 | Meaningless |
| 500 | 0.66 | 13.2 | Meaningless |
| 1000 | 0.33 | 6.6 | Meaningless |
| 2000 | 0.165 | 3.2 | 180 |
| 4000 | 0.082 | 1.6 | 91 |
| 8000 | 0.041 | 0.8 | 45 |
| 10000 | 0.033 | 0.66 | 35 |
| 15000 | 0.022 | 0.44 | 23 |

The entry “Meaningless” describes a condition where no directional effect can be determined in that the pattern is basically uniform around a complete circle. These data support the thesis that directional hearing is strongly dependent on and dominated by the hearing of the individual at frequencies above 4000 Hz and that the hearing correction at these higher frequencies is important for the directional sense of sound. These data also illustrate that the acoustic “shadowing” effect is also dominant at higher frequencies. The “shadowing” effect refers to the fact that sound emanating from one side of the head (or ear) is shadowed by the head from a direct path to the opposite ear. When the frequencies are low (2000 Hz and less) the sound “flows” around the head toward the opposite ear more efficiently that does sound at higher frequencies (4000 Hz and higher). The more restricted angular effects shown at the higher frequencies account for this difference.

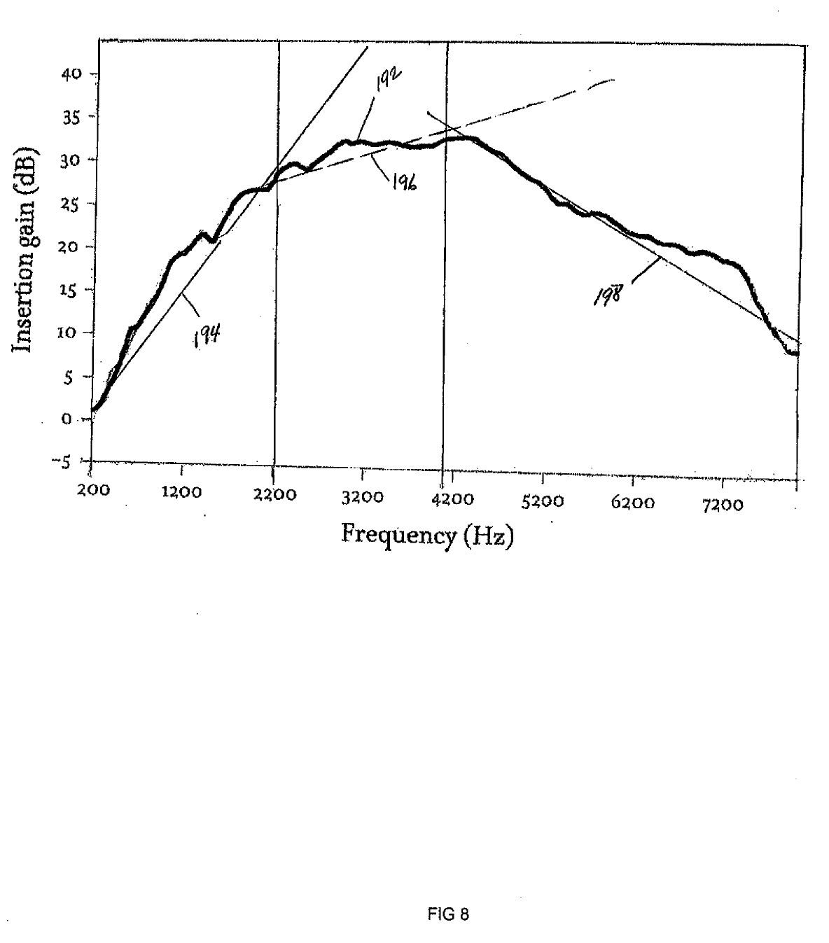

In a white paper entitled “In the Zon: Excellence and Innovation in Hearing Instrument Design”, J. A. Galster, et al. the insertion gain (hearing aid boost) for the ZON™, the latest line of hearing aids from Starkey Mfg. that is a major supplier of hearing aids. FIG. 3 of this white paper, reproduced as FIG. 8 of this application in modified form to shown only the performance of the Zon hearing aid, shows a graph of Insertion Gain in dB as a function of audio frequency (curve 192). The frequency is plotted linearly rather than logarithmically so the shape of the Insertion Gain on the more conventional log (frequency) scale can only be approximated. Also note that the response at, approximately, 200 Hz is normalized to 0 dB. By analysis of the given gain vs. frequency it is possible to characterize these data on the Log-Log plot as:
Slope up from 200 Hz to 2200 Hz from 0 db to 28 db at 8.6 dB/octave (194)
Slope up from 2200 Hz to 4000 Hz from 28 db to 33 db at 6.0 dB/octave (196).
Slope down from 4000 Hz to 8000 Hz from 33 db to 10 db at −23 dB/octave. (198).

Thus this hearing aid provides acceptable audiogram correction from 200 Hz to 2200 Hz, quite low correction to 4000 Hz, and finally a complete negative hearing correction for higher frequencies. Melding this high frequency correction into the audiogram, FIG. 4, 82, means that the user suffers a hearing degradation from the peak amplification at 4000 Hz to higher frequencies of about −29 dB/octave.

It is thus an additional object of this invention to provide large signal gain at these high frequencies. The gain is high enough that the individual with this hearing instrument should have good directional capability that comes only at high frequencies. Thus source location at an improved acceptable precision is improved, which dramatically differentiates this invention from existing hearing aid products.

The use of a compensation system that uses the circuit illustrated in FIG. 5 can be used very effectively for a very large range of such hearing impaired individuals. That is, whether the maximum hearing loss shown in an audiogram is 40 db or 70 db, the same compensated micro-speaker system has been shown to provide an extremely satisfactory hearing experience so long as the gain can be adjusted for best results by the user. This one-size-fits-all methodology gives major assistance to most of the population for which a hearing aid is needed. This factor, together with the modest price that the compensated micro-speaker system can be produced, makes this invention very useful and unique.

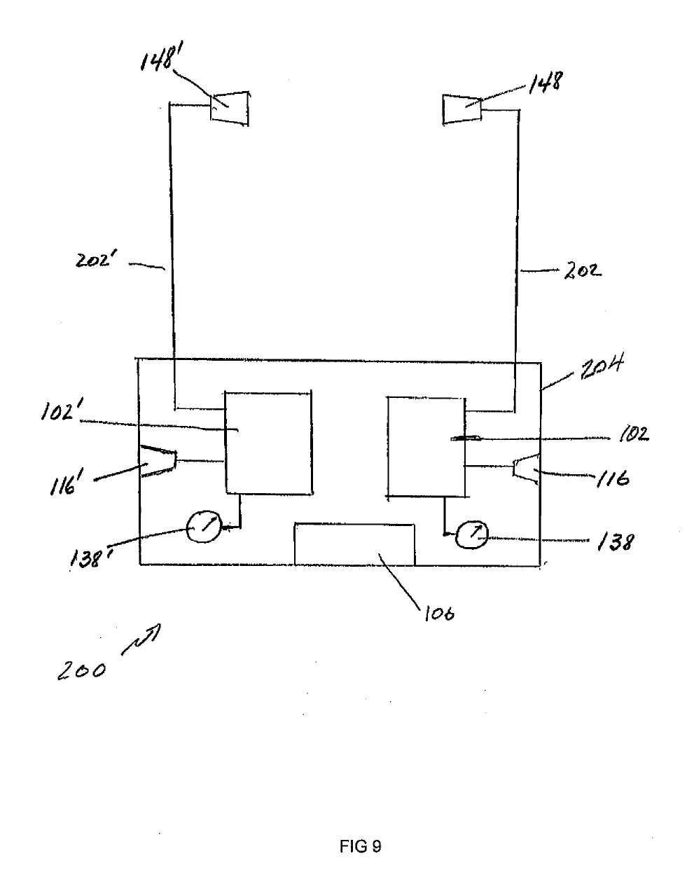

FIG. 9 shows a package layout (200) that can be used for either the “flat” or the “sensorineural-compensation” assembly. The electronics for the two ears (102, 102′) are contained in a common case (204) which can be of plastic or metal This case is expected to have dimensions of about 2.5 inches×1.75 inches×0.75 inches although larger or smaller cases might be used. Right and left microphones (116, 116′) are mounted on the right and left sides respectively of the case. Right and left volume controls (138, 138′) one of which has an off-on switch, are used by the individual to adjust the two gains. A separate slide switch for off-on power control may be used instead. The volume controls serve two purposes: (1) to compensate for the attenuation in signal caused by the filters in the right and left channels (102, 102′); and (2) to allow the user to select the gain appropriate for the hearing loss for each of his/her ears. The resultant output signals are routed to the right and left earbud micro-speakers (148, 149′) via connection flexible cables (202, 202′) that are part of the earbud set. A rechargeable Lithium-Ion battery (106) is used to provide power for the electronics and the micro-speaker and driver integrated circuit.

The case can be worn in a shirt pocket or suspended around the neck from a lanyard when the device is used as a hearing aid. It is found that wearing the hearing aid embodiment of the device beneath light weight outer clothing has a negligible effect on the performance, so the device can be worn concealed.

When the flat response is selected, for a person with normal hearing, the two microphones are removed from the circuit and a jack is used to plug in an I-Pod or MP3 player. The amplifier circuit will need to be modified to accept the output signal from the I-Pod or MP3 player output driver IC to be used as the input signal to the compensated micro-speaker amplifier. For use by hearing impaired users to hear a flat response from I-Pods and/or MP3 players it only will be necessary to modify the input parameters of the standard presbyacusis or sensorineural-hearing-loss design and then use the standard I-Pod output to drive the system. This change can be accomplished by adding a second input jack to the system that provides any electronic changes in input parameters that are required.

Whereas the drawings and accompanying description have shown and described the preferred embodiment of the present invention, it should be apparent to those skilled in the art that various changes may be made in the form of the invention without affecting the scope thereof.

We claim as follows:

1. Electronic means for flattening the audio frequency response of a micro-speaker without modifying the micro-speaker itself, the micro-speaker having a resonant peak region, the micro-speaker also having a frequency response curve that generally increases in slope (representing an increase in decibels) as the audio frequency increases up to the resonant peak region, the micro-speaker further having a frequency response curve that generally decreases in slope (representing a decrease in decibels) as the audio frequency increases beyond the resonant peak region, the means for flattening including a first circuit for flattening the frequency response curve up to the resonant peak region, the means for flattening also including a second circuit for flattening the frequency response curve for audio frequencies higher than the resonant peak region.

2. The electronic means as set forth in claim 1, wherein the first circuit includes means for flattening the audio frequency response curve over a given range of frequencies to the extent that the flattened response over such range of frequencies is in the range of plus or minus 3 dB.

3. The electronic means as set forth in claim 2, wherein the second circuit includes means for flattening the audio frequency response curve over a given range of frequencies beyond the peak resonant region to the extent that the flattened response over such range of frequencies is in the range of plus or minus 3 dB.

4. The electronic means as set forth in claim 2, wherein the first circuit includes one of the group consisting of a high pass filter and a low pass filter.

5. The electronic means as set forth in claim 4, wherein the one filter has first and second transition regions defining the range of frequencies over which the audio frequency response curve is flattened in the range of plus or minus 3 dB.

6. The electronic means as set forth in claim 4, wherein the one filter yields an integer multiple of 6 dB per octave slope.

7. The electronic means as set forth in claim 3, wherein the second circuit includes the other of the group consisting of a high pass filter and a low pass filter.

8. The electronic means as set forth in claim 7, wherein the other filter has first and second transition regions defining the range of frequencies over which the audio frequency response curve is flattened in the range of plus or minus 3 dB.

9. The electronic means as set forth in claim 7, wherein the other filter yields an integer multiple of 6 dB per octave slope.

10. The electronic means as set forth in claim 3, wherein the first circuit is in series with the second circuit, and the two circuits are in series with the micro-speaker.

11. A speaker system including a micro-speaker and electronic means for flattening the audio frequency response of the micro-speaker, the micro-speaker having a resonant peak region, the micro-speaker also having a frequency response curve that generally increases in slope (representing an increase in decibels) as the audio frequency increases up to the resonant peak region, the micro-speaker further having a frequency response curve that generally decreases in slope (representing a decrease in decibels) as the audio frequency increases beyond the resonant peak region, the means for flattening including a first circuit for flattening the frequency response curve up to the resonant peak region, the means for flattening including a second circuit for flattening the frequency response curve for audio frequencies higher than the resonant peak region.

12. A method of flattening the audio frequency response of a micro-speaker, the micro-speaker having a resonant peak region, the micro-speaker also having a frequency response curve that generally increases in slope (representing an increase in decibels) as the audio frequency increases up to the resonant peak region, the micro-speaker further having a frequency response curve that generally decreases in slope (representing a decrease in decibels) as the audio frequency increases beyond the resonant peak region, the method including the steps of:
(a) providing a low pass filter for attenuating the slope of the frequency response curve at frequencies up to the resonant peak region, the low pass filter including a first transition region where the attenuation changes from 0 dB per octave to an integer multiple of 6 dB per octave and a second transition region where the attenuation changes from an integer multiple of 6 dB per octave to 0 dB per octave;
(b) setting the first transition region at a frequency below the resonant peak area;
(c) setting the second transition region at a frequency in the resonant peak region; and
(d) flattening the frequency response curve between the frequency set for the first transition region and the resonant peak region with the low pass filter to the extent that the flattened frequency response curve is within the range of plus or minus 3 dB.

13. The method as set forth in claim 12, further including the steps of:
(a) providing a high pass filter for attenuating the slope of the frequency response curve at frequencies above the resonant peak region, the high pass filter including a first transition region where the attenuation changes from 0 dB per octave to an integer multiple of 6 dB per octave to a second transition region where the attenuation changes from an integer multiple of 6 dB per octave to 0 dB per octave;
(b) setting the first transition region of the high pass filter at a frequency in the resonant peak region;
(c) setting the second transition region of the high pass filter at a frequency above the resonant peak region; and
(d) flattening the frequency response curve between the peak resonant region and the frequency set for the second transition region of the high pass filter to the extent that the flattened frequency response curve is within the range of plus or minus 3 dB.

14. A method of correcting hearing loss in an individual, the hearing loss represented by an audiogram in which the hearing loss in decibels generally declines with increasing frequency, the method including the steps of:
(a) providing a micro-speaker having a resonant peak region, a frequency response curve that generally increases in slope (representing an increase in decibels) as the audio frequency increases up to the resonant peak region, and a frequency response curve that generally decreases in slope (representing a decrease in decibels) as the audio frequency increases beyond the resonant peak region;
(b) providing a high pass filter that has a positive integer multiple of 6 dB per octave slope which, when connected to the micro-speaker, progressively attenuates the frequency response curve as the frequency of the micro-speaker decreases;
(c) modifying the slope of the frequency response curve of the micro-speaker with the high pass filter so that the response of the micro-speaker is progressively decreased as the frequency decreases; and
(d) compensating for the signal loss in decibels caused by the attenuation.

15. The method as set forth in claim 14, wherein the step of compensating includes the step of adjusting the position of the modified frequency response curve relative to a base line to adjust the volume of sound from the micro-speaker, in decibels, by the same amount for all frequencies.

16. The method as set in claim 14, wherein the slope of the frequency response curve of the micro-speaker approximates the mirror image of the negative slope of the audiogram.

17. The method as set forth in claim 14, wherein the step of modifying the slope of the frequency response curve of the micro-speaker includes the step of providing a high pass filter having a transition region wherein the attenuation changes from 0 dB per octave to an integer multiple of 6 dB per octave.

18. The method as set forth in claim 17, further including the step of setting the transition region in the range of 10,000 Hz.

19. The method as set forth in claim 14, further including the step of providing a source of power of more than 3.0 volts.

20. The method as set forth in claim 14, further including the step of inserting the micro-speaker in an ear.

21. The method as set forth in claim 14, further including the steps of:
(a) providing a second micro-speaker having a resonant peak area, a frequency response curve that generally increases in slope as the audio frequency increase up to the resonant peak area, and a frequency response curve that generally decreases in slope as the audio frequency increases beyond the resonant peak area;
(b) providing a second high pass filter that has a positive integer multiple of 6 dB per octave slope which, when connected to the second micro-speaker, progressively attenuates the frequency response curve as the frequency of the micro-speaker decreases;
(c) modifying the slope of the frequency response curve of the second micro-speaker with the high pass filter so that the response of the second micro-speaker is progressively decreased as the frequency decreases; and
(d) compensating for the signal loss in the second micro-speaker caused by the attenuation.

22. A hearing aid comprising:
(a) a micro-speaker having a resonant peak region, a frequency response curve that generally increases in slope (representing an increase in decibels) as the audio frequency increases up to the resonant peak region, and a frequency response curve that generally decreases in slope (representing a decrease in decibels) as the audio frequency increased beyond the resonant peak region;
(b) a high pass filter that has a positive multiple integer of 6 dB per octave slope which progressively attenuates the frequency response curve of the micro-speaker as the frequency of the micro-speaker decreases;
(c) means for adjusting the volume of the micro-speaker; and
(d) a source of power.

23. A method of altering the audio frequency response of a micro-speaker, the micro-speaker having a resonant peak region, the micro-speaker also having a frequency response curve that generally increases in slope (representing an increase in decibels) as the audio frequency increases up to the resonant peak region, the micro-speaker further having a frequency response curve that generally decreases in slope (representing a decrease in decibels) as the audio frequency increases beyond the resonant peak region, the method including the steps of:
(a) providing a filter for attenuating the slope of the frequency response curve over a range of frequencies, the filter including a first transition region where the attenuation changes from 0 dB per octave to an integer multiple of 6 dB per octave;
(b) setting the first transition region at a first frequency; and
(c) modifying the frequency response curve between the frequency set for the first transition region and a second frequency.
